(19) United States
(12) Patent Application Publication
(10) Pub. No.: US 2025/0273504 A1
(43) Pub. Date: Aug. 28, 2025

(54) WAFER TRANSFER APPARATUS

(71) Applicant: Samsung Electronics Co., Ltd., Suwon-si (KR)

(72) Inventors: Seungkyu LIM, Suwon-si (KR); Taeyang HAN, Suwon-si (KR); Joowon KANG, Suwon-si (KR); Dasol KIM, Suwon-si (KR); Eunkyeom KIM, Suwon-si (KR); Changwoo SONG, Suwon-si (KR)

(73) Assignee: Samsung Electronics Co., Ltd., Suwon-si (KR)

(21) Appl. No.: 18/966,359

(22) Filed: Dec. 3, 2024

(30) Foreign Application Priority Data
Feb. 28, 2024 (KR) 10-2024-0029070

(51) Int. Cl. H01L 21/687

(52) U.S. Cl. CPC H01L 21/68707

(57) ABSTRACT

A wafer transfer apparatus includes a blade having a wafer accommodation area configured to support a wafer, a minimum contact area (MCA) support on the wafer accommodation area of the blade, a plurality of microstructures on an upper surface of the MCA support, each of the plurality of microstructures having an upper end configured to be a contact area for contacting the wafer, and a porous adsorption material between the plurality of microstructures, the porous adsorption material having a level lower than that of the contact area.

### CROSS-REFERENCE TO RELATED APPLICATION(S)

This application is based on and claims priority under 35 U.S.C. § 119 to Korean Patent Application No. 10-2024-0029070 filed on Feb. 28, 2024, in the Korean Intellectual Property Office, the disclosure of which is incorporated by reference herein in its entirety.

### BACKGROUND

Various example embodiments of the inventive concepts relate to a transfer apparatus or a processing apparatus for a wafer such as a semiconductor wafer.

A semiconductor device may be formed on a wafer (or semiconductor substrate) by a plurality of processes performed by various processing tools. These processes including, for example, chemical mechanical planarization (CMP), etching, deposition, photolithography, wet cleaning, implantation, wafer inspection, and passivation, all of which need to be performed in a sealed environment.

In this environment, the wafer in process may be transferred from one location (for example, a wafer cassette or one process chamber) to another location (for example, another process chamber) by using a wafer transfer apparatus (or a transfer robot). For higher yield of the semiconductor device, it is necessary to reduce a possibility of contamination (e.g., contamination occurring in contact of the semiconductor device with the wafer transfer apparatus) during a wafer transfer process as much as possible.

### SUMMARY

Various example embodiments provide a wafer transfer apparatus with reduced (and/or minimized) wafer contamination.

According to various example embodiments, a wafer transfer apparatus includes a blade having a wafer accommodation area configured to support a wafer, a minimum contact area (MCA) support on the wafer accommodation area of the blade, a plurality of microstructures on an upper surface of the MCA support, each of the plurality of microstructures having an upper end configured to be a contact area for contacting the wafer, and a porous adsorption material between the plurality of microstructures, the porous adsorption material having a level lower than that of the contact area.

According to other example embodiments, a wafer transfer apparatus includes a blade having a wafer accommodation area configured to support a wafer, a minimum contact area (MCA) support on the wafer accommodation area of the blade, a plurality of microspherical particles on an upper surface of the MCA support, each of the plurality of microspherical particles having an upper end configured to be a contact area for contacting the wafer, and a first depletion formation part between the plurality of microspherical particles and having a level lower than that of the contact area, the first depletion formation part including a first porous adsorption material.

According to other example embodiments, a wafer transfer apparatus includes a plurality of blades each blade respectively having a wafer accommodation area for accommodating a wafer, a robot arm connected to the plurality of blades and moving the wafer accommodation area, a plurality of minimum contact area (MCA) supports arranged on the wafer accommodation area of each of the plurality of blades, a plurality of microstructures arranged on an upper surface of each of the plurality of MCA supports, each of the plurality of microstructures having a convex upper end configured to be a contact area for contacting the wafer, and a depletion formation part including a porous adsorption material between the plurality of microstructures while having a level lower than that of the contact area. The porous adsorption material is configured to adsorb a specific gas element to provide a depletion zone where a concentration of the specific gas element is lower than a concentration of a surrounding element in areas surrounding the depletion zone.

### BRIEF DESCRIPTION OF DRAWINGS

The above and other aspects, features, and advantages of various example embodiments are more clearly understood from the following detailed description, taken in conjunction with the accompanying drawings, in which:

FIG. 1 is a schematic view illustrating a wafer processing system according to various example embodiments;

FIG. 2 is a schematic perspective view illustrating a wafer transfer apparatus introduced to the wafer processing system of FIG. 1;

FIG. 3 is a schematic perspective view illustrating an enlarged minimum contact area (MCA) structure on a blade of FIG. 2;

FIGS. 4A and 4B are scanning electron microscope (SEM) images capturing contact areas respectively on an upper surface of the MCA structure and a rear surface of a wafer, and FIG. 4C shows an overlapping composite image of the images of FIGS. 4A and 4B;

FIG. 5 is a side cross-sectional view of the MCA structure of FIG. 3 that is taken along line I-I′;

FIGS. 6A and 6B are a partial plan view and a partial cross-sectional view respectively illustrating ‘B1’ and ‘B2’ of the MCA structure introduced to various example embodiments;

FIG. 7 is a schematic view illustrating gas concentration distribution by a porous adsorption material;

FIG. 8 is a schematic view illustrating the gas concentration distribution around the MCA structure according to various example embodiments;

FIG. 9 is a side cross-sectional view illustrating an MCA structure according to other example embodiments of the present disclosure;

FIGS. 10A and 10B are a plan view and a side cross-sectional view respectively illustrating an MCA structure according to other example embodiments of the present disclosure; and

FIGS. 11A and 11B are a plan view and a side cross-sectional view respectively illustrating an MCA structure according to other example embodiments of the present disclosure.

### DETAILED DESCRIPTION

Hereinafter, various example embodiments of the present disclosure will be described in detail with reference to the accompanying drawings.

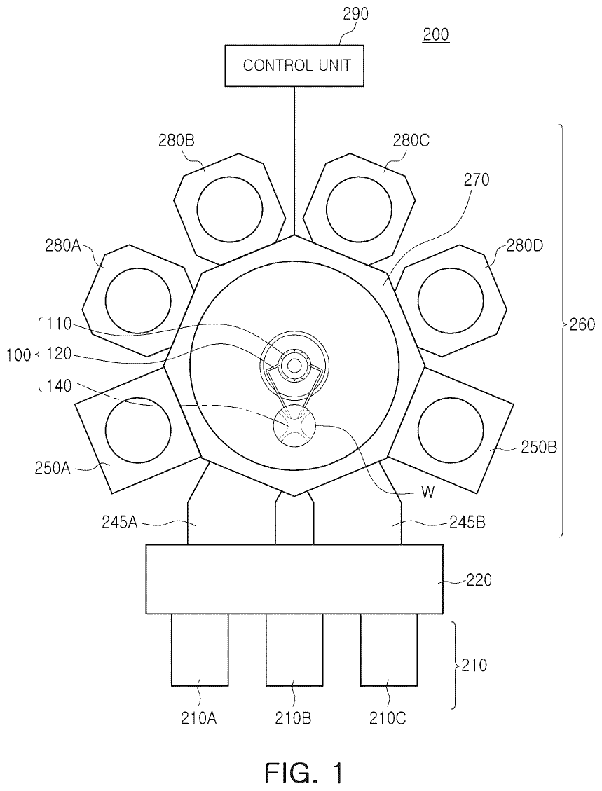

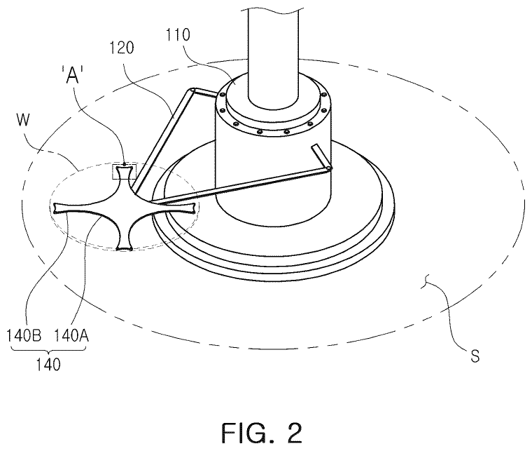

FIG. 1 is a schematic view illustrating a wafer processing system according to various example embodiments of the present disclosure; and FIG. 2 is a schematic perspective view illustrating a wafer transfer apparatus introduced to the wafer processing system of FIG. 1.

Referring to FIG. 1, a wafer processing system 200 according to various example embodiments may include a load module 220, transfer modules 100 and 270, a processing module 260, and a control unit 290.

Cassettes accommodating a plurality of wafers may be loaded into the load module 220 by using a plurality of load ports 210A, 210B, and 210C. The transfer module may include a transfer chamber 270 and a wafer transfer apparatus 100 mounted in its internal space S. Load lock chambers 245A and 245B may each be connected between the transfer chamber 270 and the load module 220. The load lock chamber 245A or 245B may provide a space for transferring a wafer W between the load module 220 and the transfer chamber 270. The load lock chambers 245A and 245B may enable decompression of the internal space.

In addition, the transfer chamber 270 may be connected to each of cleaning chambers 250A and 250B and processing chambers 280A, 280B, 280C and 280D for performing various processes. The wafer transfer apparatus 100 disposed in the internal space S of the transfer chamber 270 may withdraw the wafer W accommodated in the cassette by using the load lock chamber 245A or 245B and transfer the withdrawn wafer W to a desired chamber of the processing module 260, or transfer the wafer W from one chamber to another chamber.

The control unit 290 may be programmed for the wafer processing system 200 to perform/control various processing sequences. For example, the control unit 290 may control processing processes of various chambers, as well as the wafer transfer between the modules or between the chambers.

As shown in FIGS. 1 and 2, the wafer transfer apparatus 100 employed in various example embodiments may include a rotating unit 110 which may perform a rotational movement, robot arms 120 each mounted on the rotating unit 110 to be moved horizontally and/or vertically, and a blade 140 mounted on one end of the robot arm 120 to accommodate the wafer W.

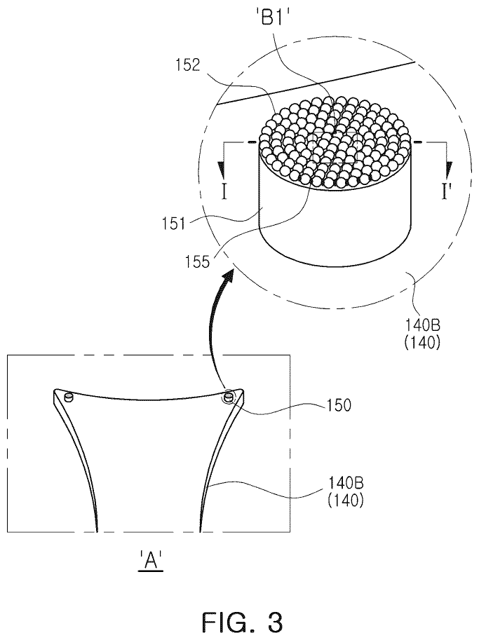

The processing chambers 280A, 280B, 280C and 280D may each include a chamber for a deposition process such as chemical vapor deposition (CVD). A thin film formed during the deposition process may contaminate a wafer accommodation portion of the blade, which may contaminate the wafer being transferred. Various example embodiments of the present disclosure provide a method of limiting or preventing the contamination of the wafer accommodation portion of the blade (in particular, a minimum contact area (MCA) support). Its details are described below in detail with reference to FIGS. 3 to 5B.

FIG. 3 is a schematic perspective view illustrating an enlarged minimum contact area (MCA) structure on the blade of FIG. 2.

Referring to FIG. 3 together with FIG. 2, the wafer transfer apparatus 100 according to various example embodiments may include a blade structure 140 having a wafer accommodation area (indicated by a dotted line).

In various example embodiments, the blade structure 140 may include four blades 140B extending in four different directions from a central connection part 140A. The blade 140B that may be employed in various example embodiments is not limited thereto, may have various structures and numbers, and be arranged to stably support the wafer W.

As shown in FIG. 3, each of the blades 140B may have a minimum contact area (MCA) structure 150 in direct contact with the wafer W in the wafer accommodation area. In various example embodiments, each of the blades 140B may have the plurality of (e.g., two) MCA structures 150 each disposed at its end corresponding to an outer peripheral area of the wafer. The blade 140B and the MCA structure 150 that may be employed in various example embodiments are not limited thereto, and in other example embodiments, the structure and number of the blade or the structure, number, and location of the MCA structure may be changed in various ways.

The MCA structure 150 may include an MCA support 151 and a plurality of microstructures 152 arranged on an upper surface of the MCA support 151. The MCA support 151 may have a structure protruding from the upper surface of the blade 140B. For example, the MCA support 151 may include a cylindrical structure. The plurality of microstructures 152 may each have an upper end provided as a “minimum contact area (MCA)” in contact with the wafer.

In this way, the wafer transfer apparatus 100 according to various example embodiments may reduce the contamination of the wafer W by reducing a contact area thereof with the wafer W to be transferred using the MCA structure 150, in particular, the microstructures 152. Contamination of a rear surface of the wafer may cause a defect during a photolithography process. Therefore, the wafer transfer apparatus 100 may secure an improved process yield of a semiconductor device by reducing a contact area thereof with the wafer by using the MCA structure. However, the unwanted thin film may still exist in the contact area of the MCA structure, and it is thus difficult to fundamentally eliminate the contamination of the rear surface of the wafer.

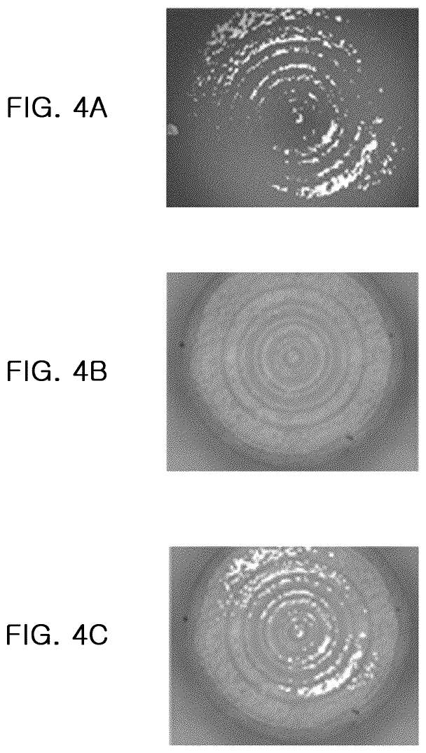

FIGS. 4A and 4B are scanning electron microscope (SEM) images capturing the contact areas respectively on an upper surface of the MCA structure and a rear surface of a wafer, and FIG. 4C shows an image generated by combining a contamination pattern in FIG. 4A and a pattern image of the upper surface of the MCA structure that is shown in FIG. 4B.

It may be seen that referring to FIG. 4A, the contamination has a concentric circle shape and occurs in the contact area of the rear surface of the transferred wafer, and referring to FIG. 4C, the contamination pattern in FIG. 4A corresponds to a contact area pattern of the MCA structure in FIG. 4B. As described above, the contamination may occur based on an upper surface pattern of the MCA structure, that is, the contact area pattern, thus requiring a more effective method of limiting or preventing the contamination caused by its contact with the MCA structure.

Various example embodiments may provide a method of limiting or preventing the contamination of the rear surface of the wafer that occurs due to a thin film material deposited during the wafer transfer by using a porous adsorption material to thus suppress the thin film deposition in the contact area of the MCA structure, in particular, the microstructure 152 during the thin film deposition.

FIG. 5 is a side cross-sectional view of the MCA structure of FIG. 3 that is taken along line I-I′.

Referring to FIG. 5, the MCA structure 150 according to various example embodiments may include a porous adsorption material 155 disposed between the microstructures 152. In various example embodiments, the microstructure 152 may include spherical particles. For example, the spherical particle may have a diameter of 1 μm to 100 μm. The microstructures 152 may have one layer in which the spherical particles are densely arranged on the upper surface of the MCA support 151. The porous adsorption material 155 may be disposed to be closer to the upper end of the microstructure 152 to reduce or prevent the contamination caused by the unwanted thin film deposition in a contact area CP.

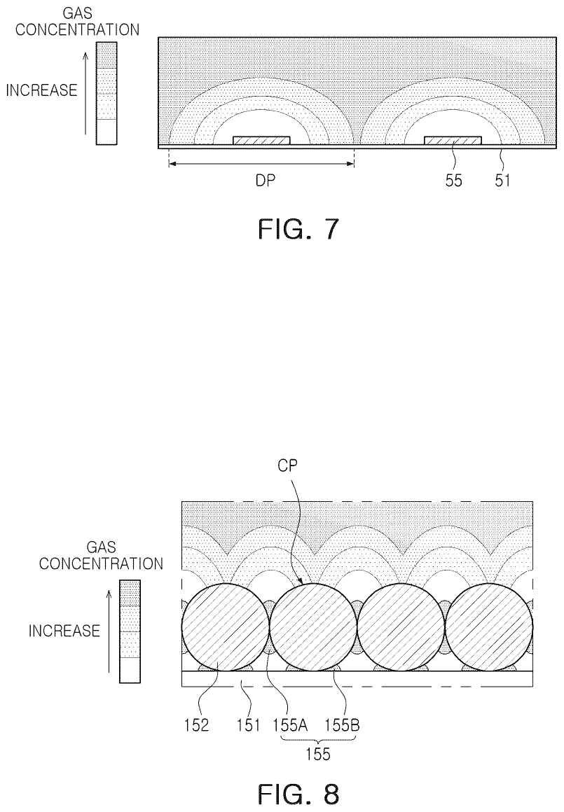

The porous adsorption material 155 employed in various example embodiments refers to a material that adsorbs a specific gas element used in the deposition process, such as CVD or physical vapor deposition (PVD). For example, each pore of the porous adsorption material 155 may have a size of 1 nm to 1000 nm. This porous adsorption material 155 may provide a depletion zone where concentration of the specific source gas element is lower than concentration of another surrounding element. Various example embodiments may reduce or prevent the contamination of the contact area of the MCA structure with the wafer during the deposition process (see FIGS. 7 and 8) by disposing the porous adsorption material 155 for the upper end of the microstructure 152, that is, the contact area, in the depletion zone.

For example, the porous adsorption material 155 may include a porous material including at least one of activated silica, activated alumina, activated carbon, activated clay, and synthetic zeolite. However, example embodiments are not limited thereto.

The porous adsorption material may use a material that has a relatively better adsorption property with the specific source gas compared to a material included in the microstructure. The porous adsorption material 155 may be appropriately selected based on a type of gas component to be adsorbed.

In some example embodiments, the porous adsorption material 155 may be a hydrophilic material advantageous for adsorbing moisture, and include, for example, activated clay, activated silica (or silica gel), activated alumina, or synthetic zeolite. However, example embodiments are not limited thereto. In some example embodiments, the porous adsorption material 155 may be a hydrophobic material advantageous for adsorbing a non-polar or slightly polar substance, and include, for example, activated carbon such as charcoal or bone charcoal. However, example embodiments are not limited thereto.

In various example embodiments, silica gel and activated alumina may be usefully used as the porous adsorption material 155 which has a molecular structure with electrical polarity or adsorbs a polar compound with lone pairs. In addition, activated carbon as the porous adsorption material 155 may have a tendency to adsorb the compound having a high molecular weight (e.g., hydrocarbons such as benzene).

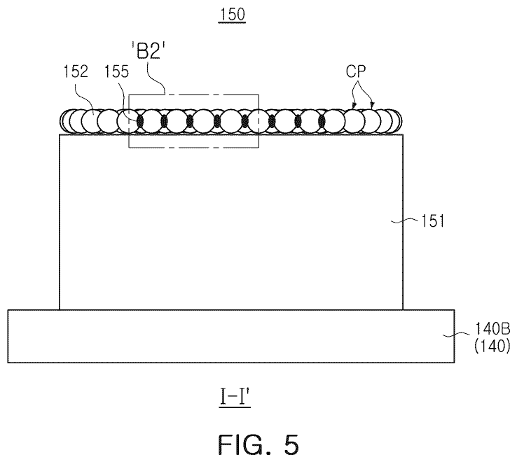

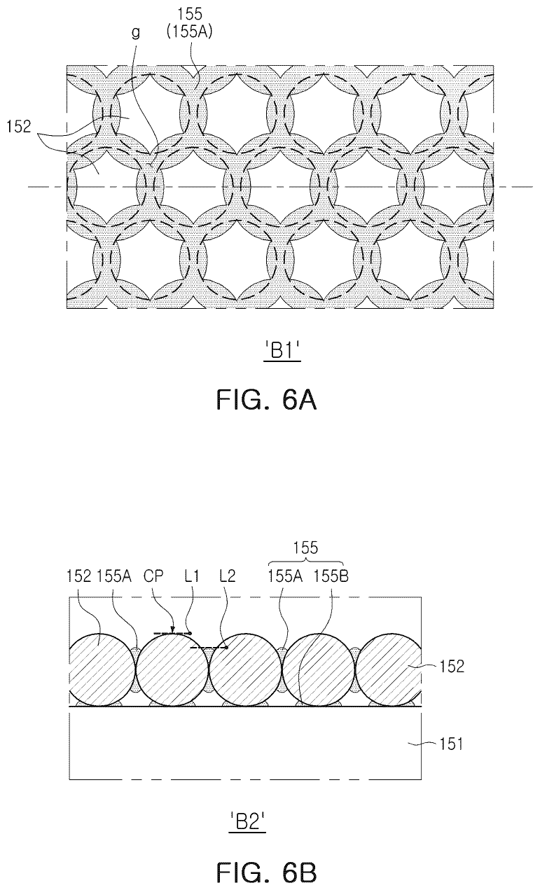

As described above, the porous adsorption material 155 has a property of being adsorbed to the specific gas component, thus providing the depletion zone where the concentration of the specific source gas element is lower than the concentration of another surrounding element. The porous adsorption material 155 may be disposed in an appropriate area for the contact area CP of the microstructure 152 to be disposed in the depletion zone. The description describes the placement of the porous adsorption material 155 introduced to various example embodiments with reference to FIGS. 6A and 6B.

FIGS. 6A and 6B are a partial plan view and a partial cross-sectional view respectively illustrating ‘B1’ and ‘B2’ of the MCA support introduced to various example embodiments.

Referring to FIGS. 6A and 6B, the porous adsorption material 155 introduced by the various example embodiments may be classified into first and second porous adsorption materials 155A and 155B based on their locations. The first porous adsorption material 155A may be disposed between the microstructures 152 while having a level L2 lower than a level L1 of the contact area CP. The first porous adsorption material 155A may be absorbed by gas molecules to thus reduce the surrounding gas concentration.

In particular, referring to FIG. 6A, the first porous adsorption materials 155A may be arranged between the microstructures 152 while having a honeycomb shape to thus effectively form the depletion zone over an entire area where the microstructures 152 are arranged.

The porous adsorption material 155 introduced by the various example embodiments may include the second porous adsorption material 155B further disposed around the plurality of microstructures 152 on the upper surface of an MCA support 151. The porous adsorption material 155 disposed in this way may form the depletion zone for the contact area CP to be disposed therein. The description describes a principle of forming the depletion zone with reference to FIGS. 7 and 8.

FIG. 7 is a schematic view illustrating gas concentration distribution by the porous adsorption material 155; and FIG. 8 is a schematic view illustrating the gas concentration distribution around an MCA structure 152 according to various example embodiments of the present disclosure.

FIG. 7 first shows that porous adsorption material patterns 55 are formed on a substrate 51 while having a desired (and/or alternatively predetermined) gap therebetween. In this case, the gas around the porous adsorption material pattern 55 may be adsorbed to the porous adsorption material pattern 55. During a process of the adsorption, a concentration gradient may be generated around the porous adsorption material pattern 55 due to gas diffusion. As shown in FIG. 7, this concentration gradient may lower the gas concentration as being closer to the porous adsorption material pattern 55, thus forming a depletion zone DP in a certain distance therefrom.

FIG. 8 shows a partial area of the MCA structure shown in FIG. 5B. Similar to the formation of the depletion zone DP described with reference to FIG. 7, the porous adsorption material 155 may form the depletion zone having a lower gas concentration around the material by the gas adsorption. The contact area CP may be disposed in the depletion zone. In particular, the first porous adsorption material 155A may be disposed to be close to the contact area CP, thus greatly contributing to forming the depletion zone around the contact area CP even though the first porous adsorption material 155A disposed between the microstructures 152 has a lower level than the level L1 of the contact area CP of the microstructure 152. In this way, the gas concentration may be relatively low in the depletion zone, thus limiting or preventing thin film nucleation from occurring on the contact area CP of the microstructure 152 disposed in the depletion zone. As a result, it is possible to reduce or prevent the thin film, which acts as a contaminant, from being formed in the contact area CP of the microstructure 152. The second porous adsorption material 155B may also contribute to the formation of the depletion zone by being disposed around the microstructure 152 on the upper surface of the MCA support 151. In the specification, the first and second porous adsorption materials 155A and 155B are respectively also referred to as “first and second depletion formation areas”.

It is possible to suppress the thin film formation on the contact area CP of the microstructure 152 during the deposition process, and transfer the wafer W by using the wafer transfer apparatus 100 according to various example embodiments after the deposition process. During the wafer transfer process, even in case that the contact area CP of the microstructure 152 is in contact with the rear surface of the wafer W, not only is the contact area CP reduced by the microstructure 152, and but also there may be almost no contaminants to be transferred to the contact area CP by the porous adsorption material 155 disposed between the microstructure 152. As a result, it is possible to reduce (and/or minimize) the contamination of the rear surface of the wafer W (see FIGS. 1 to 4).

The microstructures 152 shown in FIGS. 3, 5A, and 5B may be arranged using a method of suspending the spherical particles in a liquid phase (e.g., liquid-gas interface) and transferring the same to a target surface (e.g., upper surface of the MCA support). In addition, the porous adsorption material 155 may be formed between the microstructures 152 by using a colloidal lithography process. For example, an accommodation solution including the porous adsorption material 155 may be prepared, and the porous adsorption material 155 may be disposed between the microstructures by using a capillary flow generated during an evaporation process of a liquid in the accommodation solution (presented by T. Han et al., “Sustainable thin-film condensation with free surface flow through water film network,” International Journal of Heat and Mass Transfer, 2022). In case of performing colloidal lithography, the porous adsorption material 155 may be formed in a relatively narrow gap between the spherical microstructures 152, as shown in FIGS. 6A and 6B.

The microstructure 152 and the porous adsorption material 155 are not limited thereto. The microstructure 152 may be formed using processes such as micro milling, laser processing, and the lithography, and the porous adsorption material 155 may be formed using processes such as microprinting and the laser processing.

The MCA structure according to these example embodiments may have various different structures by different processes from the previous example embodiments. For example, the MCA structure shown in FIG. 3 may have the spherical microstructures formed in one layer by using various processes such as the method of the transfer to the upper surface of MCA support. Alternatively, the MCA structure may have the microstructures arranged in a plurality of layers, and have more of the porous adsorption materials each disposed between the microstructures by using the process such as the colloidal lithography.

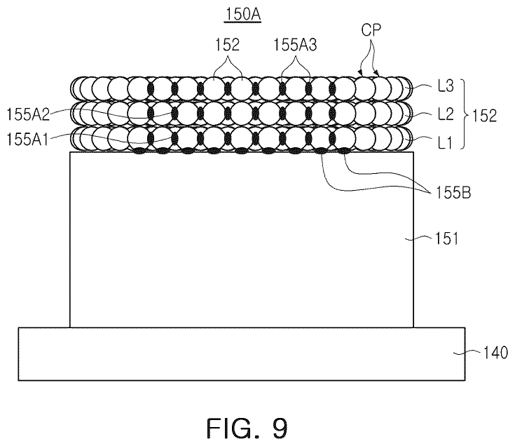

FIG. 9 is a side cross-sectional view illustrating an MCA structure according to other example embodiments of the present disclosure.

It may be understood that an MCA structure 150A according to various example embodiments is similar to the MCA structure 150 shown in FIGS. 5, 6A, and 6B except for the fact that the MCA structure 150A has the microstructures 152 in which a plurality of layers L1, L2, and L3 are arranged, and the porous adsorption materials 155A1, 155A2, 155A3, and 155B provided on each layer L1, L2, or L3. In addition, unless otherwise stated, the components of various example embodiments may be understood with reference to the description of the same or similar components of the MCA structure 150 shown in FIGS. 5, 6A, and 6B.

In various example embodiments, the microstructure 152 may include three layers L1, L2, and L3, each of which has the spherical particles densely arranged. The microstructure 152 of the plurality of layers may be formed using the process such as the colloidal lithography. The porous adsorption materials 155A1, 155A2, and 155A3 may respectively be applied between the microstructures 152 of the respective layers. On the upper surface of the MCA support 151, the porous adsorption materials 155B may be applied around the microstructures 152 of the first layer L1. In some example embodiments, the porous adsorption materials 155A1, 155A2, and 155A3 may be formed using the colloidal lithography process. It is possible to form the three-layered microstructures 152 including the spherical particles, and the porous adsorption materials 155A1, 155A2, 155A3, and 155B may then be arranged in the relatively narrow gap between the microstructures 152 by using the colloidal lithography process.

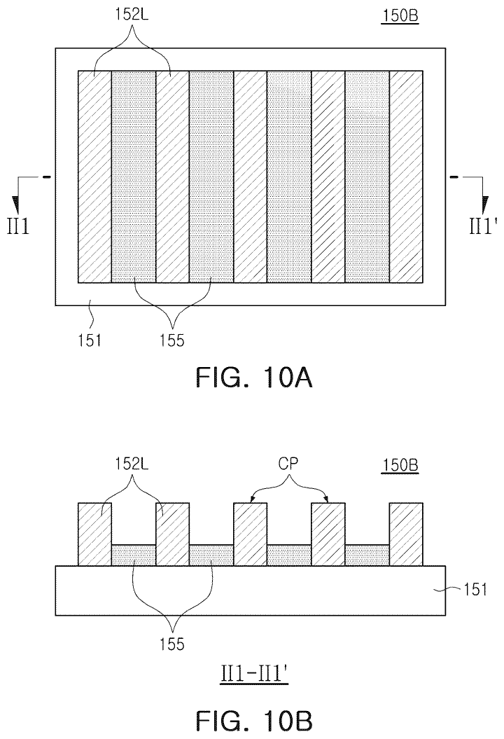

FIG. 10A is a plan view illustrating an MCA structure according to other various example embodiments of the present disclosure, and FIG. 10B is a cross-sectional view of the MCA structure of FIG. 10A that is taken along line II1-II1′.

It may be understood that an MCA structure 150B according to various example embodiments is similar to the MCA structure 150 shown in FIGS. 5, 6A, and 6B except for the fact that the MCA structure 150B has microstructures 152L formed in line patterns, and the porous adsorption material 155 disposed between the microstructures 152L on the upper surface of the MCA support 151. In addition, unless otherwise stated, the components of various example embodiments may be understood with reference to the description of the same or similar components of the MCA structure 150 shown in FIGS. 5, 6A, and 6B.

The microstructures 152L according to various example embodiments may include the line patterns arranged in one direction. For example, the microstructures 152L may each have a width of 1 μm to 100 μm and may be arranged while having a gap of 1 μm to 100 μm therebetween. These microstructures 152L may be formed using the micro milling, the laser processing, or photo lithography/etching. In some example embodiments, the microstructure 152L may be formed by etching the upper area of the MCA support 151. For example, the microstructure 152L may include the same material as the MCA support 151. The porous adsorption material 155 may be disposed between the microstructures 152L on the upper surface of the MCA support 151. The porous adsorption material 155 may have an upper surface whose level is lower than the level of the contact area CP of the microstructures 152L.

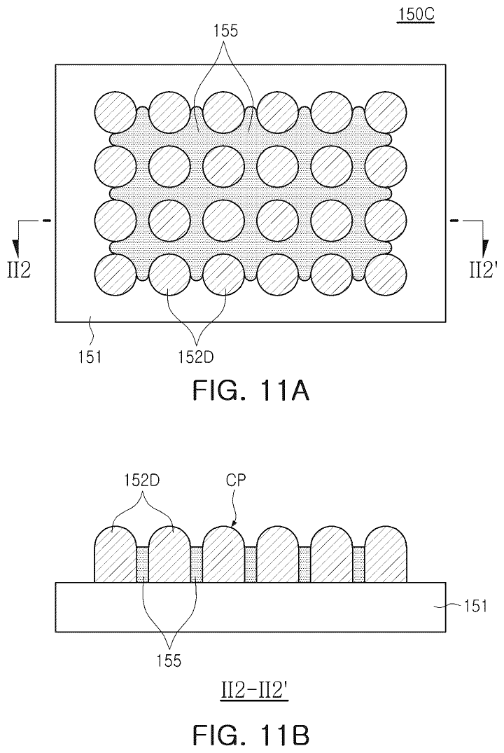

FIG. 11A is a plan view illustrating an MCA structure according to other various example embodiments of the present disclosure, and FIG. 11B is a cross-sectional view of the MCA structure of FIG. 11A that is taken along line II2-1I2′.

It may be understood that an MCA structure 150C according to various example embodiments is similar to the MCA structure 150 shown in FIGS. 5, 6A, and 6B except for the fact that the MCA structure 150C has microstructures 152D formed in dot patterns, and the porous adsorption material 155 disposed between the microstructures 152D on the upper surface of the MCA support 151. In addition, unless otherwise stated, the components of various example embodiments may be understood with reference to the description of the same or similar components of the MCA structure 150 shown in FIGS. 5, 6A, and 6B.

The microstructures 152D according to various example embodiments may include the plurality of dot patterns. For example, the microstructures 152D may each have a width of 1 μm to 100 μm and may be arranged while having a gap of 1 μm to 100 μm therebetween. The microstructure 152D may have a convex upper end, thereby reducing an area of the contact area CP. Similar to the previous example embodiments, these microstructures 152D may be formed using the micro milling, the laser processing, or the photo lithography/etching. In some example embodiments, the microstructure 152D may be formed by etching the upper area of the MCA support 151. That is, the microstructure 152D may include the same material as the MCA support 151. The porous adsorption material 155 may be formed between the microstructures 152D on the upper surface of the MCA support 151. The porous adsorption material 155 may have the upper surface whose level is lower than the level of the contact area CP of the microstructures 152D.

As set forth above, according to the example embodiments described above, various example embodiments may reduce or prevent the contamination caused by the contact of the wafer with the MCA support during the wafer transfer process by suppressing the adsorption of the source gas to its portion in contact with the wafer, arranging the microstructures on the MCA support, and applying the porous adsorption material that induces the adsorption of the source gas, used in the deposition process, around the contact area of the microstructure.

Various and beneficial advantages and effects of various example embodiments are not limited to those described above, and may be more readily understood in the process of describing specific example embodiments of the present disclosure.

Various example embodiments of the present disclosure have been described hereinabove with reference to the accompanying drawings. However, it is to be understood by those skilled in the art to which the present disclosure pertains that various modifications and alterations may be made without departing from the technical spirit or essential feature of the present disclosure. Therefore, it is to be understood that the example embodiments described hereinabove are illustrative rather than restrictive in all respects.

What is claimed is:

1. A wafer transfer apparatus comprising:
a blade having a wafer accommodation area configured to support a wafer;
a minimum contact area (MCA) support on the wafer accommodation area of the blade;
a plurality of microstructures on an upper surface of the MCA support, each of the plurality of microstructures having an upper end configured to be a contact area for contacting the wafer; and
a porous adsorption material between the plurality of microstructures, the porous adsorption material having a level lower than that of the contact area.

2. The apparatus of claim 1, wherein
the porous adsorption material includes a porous material including at least one of activated silica, activated alumina, activated carbon, activated clay, or synthetic zeolite.

3. The apparatus of claim 1, wherein
each pore of the porous adsorption material has a size of 1 nm to 1000 nm.

4. The apparatus of claim 1, wherein
the microstructure includes spherical particles, each having a diameter of 1 μm to 100 μm.

5. The apparatus of claim 4, wherein
the spherical particles are densely arranged in one layer.

6. The apparatus of claim 5, wherein
the porous adsorption material is further around each of the spherical particles on the upper surface of the MCA support.

7. The apparatus of claim 4, wherein
the spherical particles are arranged in a plurality of layers and each of microstructures of the uppermost layer among the plurality of layers has the contact area.

8. The apparatus of claim 7, wherein
the porous adsorption material is in an area between the plurality of layers of the spherical particles.

9. The apparatus of claim 1, wherein
the microstructure includes line patterns or dot patterns, each having a width of 1 μm to 100 μm.

10. The apparatus of claim 9, wherein
the microstructure includes a same material as the MCA support.

11. The apparatus of claim 9, wherein
each of the microstructures has a convex upper surface.

12. A wafer transfer apparatus comprising:
a blade having a wafer accommodation area configured to support a wafer;
a minimum contact area (MCA) support on the wafer accommodation area of the blade;
a plurality of microspherical particles on an upper surface of the MCA support, each of the plurality of microspherical particles having an upper end configured to be a contact area for contacting the wafer; and
a first depletion formation part between the plurality of microspherical particles and having a level lower than that of the contact area, the first depletion formation part including a first porous adsorption material.

13. The apparatus of claim 12, further comprising
a second depletion formation part around the plurality of microspherical particles on the upper surface of the MCA support, and including a second porous adsorption material.

14. The apparatus of claim 13, wherein
at least one of the first and second porous adsorption materials includes a porous material including at least one of activated silica, activated alumina, activated clay, or synthetic zeolite.

15. The apparatus of claim 13, wherein
at least one of the first and second porous adsorption materials includes a porous material including activated carbon.

16. The apparatus of claim 13, wherein
the first and second porous adsorption materials include a same material.

17. The apparatus of claim 12, wherein
the microspherical particles are densely arranged in one layer.

18. A wafer transfer apparatus comprising:
a plurality of blades, each blade respectively having a wafer accommodation area for accommodating a wafer;
a robot arm connected to the plurality of blades and moving the wafer accommodation area;
a plurality of minimum contact area (MCA) supports arranged on the wafer accommodation area of each of the plurality of blades;
a plurality of microstructures arranged on an upper surface of each of the plurality of MCA supports, each of the plurality of microstructures having a convex upper end configured to be a contact area for contacting the wafer; and
a depletion formation part including a porous adsorption material between the plurality of microstructures while having a level lower than that of the contact area, and
wherein the porous adsorption material is configured to adsorb a specific gas element to provide a depletion zone where a concentration of the specific gas element is lower than a concentration of a surrounding element in areas surrounding the depletion zone.

19. The apparatus of claim 18, wherein
the plurality of microstructures include the spherical particles densely arranged in one layer.

20. The apparatus of claim 18, wherein the plurality of microstructures include at least one of a plurality of line patterns and a plurality of dot patterns.
